(19) United States
(12) Patent Application Publication
(10) Pub. No.: US 2026/0239893 A1
(43) Pub. Date: Aug. 13, 2026

(54) MULTI-STATE MEMORY COMPRISING TUNNEL JUNCTIONS WITH TOPOLOGICALLY STABILIZED STRUCTURES

(71) Applicants: THALES, COURBEVOIE (FR); Centre national de la recherche scientifique, PARIS (FR)

(72) Inventors: Manuel BIBES, PARIS (FR); Vincent GARCIA, PARIS (FR); Romain LEBRUN, PALAISEAU CEDEX (FR)

(21) Appl. No.: 18/724,413

(22) PCT Filed: Dec. 26, 2022
(86) PCT No.: PCT/EP2022/087842

§ 371 Date: Sep. 4, 2025

(30) Foreign Application Priority Data
Dec. 27, 2021 (FR) FR2114540

(51) Int. Cl. H10N 70/20; H10B 63/00; H10N 70/00

(52) U.S. Cl. CPC H10N 70/25; H10B 63/00; H10N 70/257; H10N 70/8836

(57) ABSTRACT

A tunnel junction presenting a stack formed by a barrier and two electrodes, the barrier comprising a layer of ferroelectric material, so-called ferroelectric layer, the ferroelectric layer including at least one topologically protected structure presenting properties, the tunnel junction further including a unit for monitoring the properties of the at least one topologically protected structure.

### CROSS-REFERENCE TO RELATED APPLICATIONS

This application claims benefit under 35 USC § 371 of PCT Application N. PCT/EP2022/087842 entitled MULTI-STATE MEMORY COMPRISING TUNBNEL JUNCTIONS WITH TOPOLOGICALLY STABILISED STRUCTURES, filed on Dec. 26, 2022 by inventors Manuel Bibes, Vincent Garcia and Romain Lebrun. PCT Application No. PCT/EP2022/087842 claims priority of French Patent Application No. 21 14540, filed on Dec. 27, 2021.

### FIELD OF THE INVENTION

The present invention relates to a tunnel junction and a memory comprising such a tunnel junction.

Thus, the present invention falls within the field of thin film heterostructures that can be employed as non-volatile random access memory elements.

### BACKGROUND OF THE INVENTION

To increase information storage density (which also leads to a reduction in cost), it is desirable to use components allowing to store more than just binary 0 or 1 information (a single bit), but rather several bits. For example, if each element can store 3 bits, that is, 8 different values (2³=8), 4 times more information can be stored for the same surface area used.

In microelectronic systems of today, non-volatile information storage is mainly ensured by magnetic hard disks (inexpensive, but slow and fragile) and non-volatile random access memories (often referred to by the abbreviation NVRAM) such as flash memories.

Traditionally, each memory element encoded a single bit, but recent developments have seen the emergence of Flash NAND memories encoding several bits. Furthermore, three-dimensional memories are also being developed, in which several bits can be stored on the same useful surface.

However, this results in a more complex architecture. Added to this shortcoming is the fact that flash memories traditionally suffer from relatively low endurance, limiting their range of use. Moreover, the endurance of multi-bit Flash memories is one to two orders of magnitude lower than that of binary memories.

This is why analog memory element technologies possessing a near-infinite number of intermediate states-memristors-have recently been proposed for use as multibit digital memories.

A memristor is a component whose electrical resistance changes permanently when a current is applied. Thus, data can be recorded and rewritten by a control current. Such behavior is notably seen in phase-change memories, ferroelectric tunnel junctions or redox memories based on oxides such as TIO₂.

Generally speaking, however, the error rate of multibit memories is higher than that of traditional binary memories.

In the case of memories formed by memristors, the reproducibility and stability of intermediate resistance states is not necessarily very good; in particular, a drift in the resistance value is observed as the state is read (linked in fact to their memristive character).

As a result, error correction codes have been known to be used to correct the error, which complicates read/write algorithms and slows down the system.

There is therefore a need for a faster, error limited multi-state memory.

### SUMMARY OF THE DESCRIPTION

To this end, the description describes a tunnel junction presenting a stack formed by a barrier and two electrodes, the barrier comprising a layer of a ferroelectric material, the so-called ferroelectric layer, the ferroelectric layer including at least one topologically protected structure presenting properties, the tunnel junction further including a unit for monitoring the properties of the at least one topologically protected structure.

According to particular embodiments, the tunnel junction presents one or more of the following features, taken alone or according to any technically possible combination:
the barrier presents a thickness of less than or equal to 15 nanometers.
the topologically protected structure is chosen from the list constituted of: a skyrmion, an antiskyrmion, a meron, an anmeron, a hopfion, a biskyrmion, a skyrmonium and an antiferromagnetic skyrmion.
the number of topologically protected structures is less than or equal to 10,000 and each topologically protected structure presents a size of between 1 nanometer and 100 nanometers.
the control unit includes at least one subunit chosen from among a subunit for generating topologically protected structures and a subunit for destroying topologically protected structures.
the control unit includes a subunit for adjusting at least one property of the topologically protected structure, the adjustment subunit being able to control temperature or to control stresses by tension.
each subunit includes an electrical source or an optical source.
the tunnel junction further includes a subunit for reading at least one property of the topologically protected structures, the reading subunit being able to measure a resistance or an optical index.
the ferroelectric layer is made of a ferroelectric material selected from the list consisting of Ba₁₋ₓSrₓTiO₃, PbTiO₃, Bi₁₋ₓLaₓFeO₃, PbZrₓTi₁₋ₓO₃, Hf₁₋ₓZrₓO₂ or KNbO₃, x being a variable between 0 and 1.
the barrier includes at least one dielectric layer in contact with the ferroelectric layer, the dielectric layer being, for example, made of a material selected from among the list constituted of SrTiO₃, KTaO₃, LaAlO₃, (Dy, Tb, Gd, Sm, Nd, La)ScO₃, NdGaO₃, HfO₂, ZrO₂, Y₂O₃ and Al₂O₃.
the barrier is a stack of several identical patterns, each pattern including at least one ferroelectric layer and one dielectric layer, each ferroelectric layer being made of a ferroelectric material selected from the list constituted of Ba₁₋ₓSrₓTiO₃, PbTiO₃, Bi₁₋ₓLaₓFeO₃, PbZrₓTi₁₋ₓO₃, Hf₁₋ₓZrₓO₂ and KNbO₃, x being a variable between 0 and 1, and each dielectric layer (26, 28) being made of a material selected from among the list constituted of SrTiO₃, KTaO₃, LaAlO₃, (Dy, Tb, Gd, Sm, Nd, La)ScO₃, NdGaO₃, HfO₂, ZrO₂, Y₂O₃ and Al₂O₃.
the electrodes are selected from among the list constituted of La₁₋ₓSrₓMnO₃, La₁₋ₓCaₓMnO₃, Ca₁₋ₓCaₓMnO₃, BaₓSr₁₋ₓRuO₃, BaPbO₃, LaNiO₃, La₁₋ₓSrₓTiO₃, RuO₂, conductive indium tin oxide, TiN, Pt, Au and Pd, x being a variable between 0 and 1.

The description also describes a memory including a tunnel junction as previously described.

### BRIEF DESCRIPTION OF THE DRAWINGS

Further features and advantages of the invention will become apparent from the following description, given solely by way of non-limiting example, and made with reference to the appended drawings, in which:

FIG. 1 is a schematic view of an example of a memory comprising a tunnel junction, and

FIG. 2 is a schematic representation of another example of a tunnel junction.

### DETAILED DESCRIPTION OF EMBODIMENTS

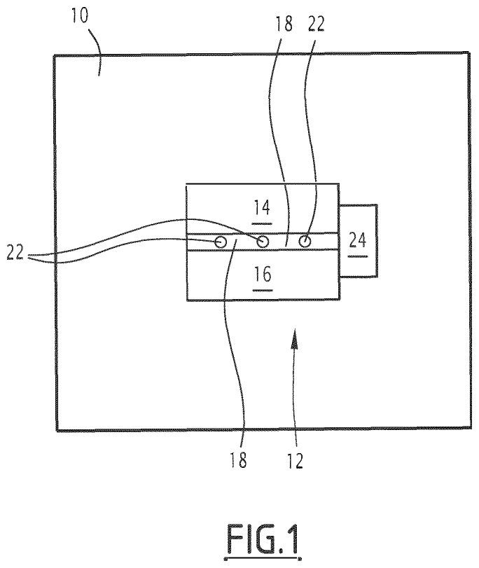

A memory 10 is shown in FIG. 1.

The memory 10 is a multi-state memory, in other words, a memory possessing several storage states.

Such a memory 10 is able to be used in information storage and in a neuromorphic computing system.

To realize this multi-state memory, the memory 10 includes a tunnel junction 12, which will now be described.

The tunnel junction 12 includes two electrodes 14 and 16 as well as a barrier 18.

The two electrodes 14 and 16 are conductive electrodes.

Each electrode 14 or 16 is made of either conductive or semiconducting materials.

The electrodes 14, 16 are made of a non-ferroelectric material selected from the list constituted of La₁₋ₓSrₓMnO₃, La₁₋ₓCaₓMnO₃, Ca₁₋ₓCeₓMnO₃, BaₓSr₁₋ₓRuO₃, BaPbO₃, LaNiO₃, La₁₋ₓSrₓTiO₃, RuO₂, ITO (conductive indium tin oxide), TiN, Pt, Au and Pd.

Unless otherwise stated, in each of the materials to be mentioned, the variable x is between 0 and 1.

The barrier 18 is interposed between the two electrodes 14 and 16 so that electrodes 14, 16 and the barrier 18 form a stack of superimposed layers along a stacking direction. The first electrode 14 is thus sometimes referred to as the upper electrode, while the second electrode 16 is similarly referred to as the lower electrode.

The layer thickness is, in the following, the dimension of a layer along the stacking direction.

Objects such as electrons can pass from one electrode 14 or 16 to the other electrode 14 or 16 through the barrier 18 by a tunnel effect (a quantum property allowing an object to pass through a potential barrier even if its energy is less than the minimum energy required to pass through that barrier).

The barrier 18 presents a thickness of less than or equal to 15 nanometers (nm).

The barrier 18 includes a layer of ferroelectric material 20, hereinafter referred to as the ferroelectric layer 20. For example, the ferroelectric material is strontium barium titanate with the chemical formula Ba₁₋ₓSrₓTIO₃.

Alternatively, the ferroelectric material is PbTiO₃, BiₓLa₁₋ₓFeO₃, PbZrₓTi₁₋ₓO₃, HfₓZr₁₋ₓO₂ or KNbO₃.

Due to the presence of the ferroelectric material in the barrier layer 18, the tunnel junction 12 is a ferroelectric tunnel junction.

The ferroelectric layer 20 includes at least one ferroelectric skyrmion 22.

The number of ferroelectric skyrmions 22 in the ferroelectric layer 20 is less than or equal to 10,000.

By way of illustration, three ferroelectric skyrmions 22 are shown in FIG. 1.

The ferroelectric skyrmions 22 present a size between 1 nm and 10 nm.

The ferroelectric skyrmions 22 thus possess a very small size, making them extremely interesting objects for ultra-high-density information storage.

It may also be noted that the ferroelectric skyrmions 22 are all fairly similar in size; typically, the variation in size between two ferroelectric skyrmions 22 is less than 30%.

The ferroelectric skyrmions correspond to chiral configurations of electric dipoles winding according to all directions in space.

The ferroelectric skyrmions are thus electrical analogues of magnetic skyrmions.

Each ferroelectric skyrmion 22 presents its own properties.

The term “property” is used here in a very broad sense, knowing that the existence of the ferroelectric skyrmion 22 is also regarded as a property in addition to the value of physical quantities that could be measured on the ferroelectric skyrmion 22.

In particular, in the same way as magnetic skyrmions, the ferroelectric skyrmions possess a topological charge that ensures additional stability. The ferroelectric skyrmions possess a topological character in the sense that the normalized integral of the direction of the polarization vector over the volume of the skyrmion is a non-zero integer, typically 1 (topological charge), and potentially a fraction.

This topological character provides additional stability to the ferroelectric skyrmion, as its destruction (corresponding to the reorientation of all electric dipoles according to a parallel direction) requires the input of energy equivalent to the maximum energy of the system, in this case, the exchange energy. This phenomenon is sometimes explained by the analogy of a knot on a string: to remove the knot, you have to break the string.

From a practical point of view, this means that the application of an electric field allows the skyrmions to be created or eliminated, but these are unaffected by weaker energy inputs linked, for example, to temperature (as long as the latter is within 50° C. of the ordering temperature).

A ferroelectric skyrmion is therefore a topologically protected structure, in other words, a structure including a topological charge that is conserved.

The tunnel junction 12 also comprises a control unit 24 allowing at least one of the properties of the ferroelectric skyrmions 22 to be controlled.

The term “control” is to be understood here in the broadest sense as referring, on the one hand, to a function of manipulating or modifying a property, but also, on the other hand, to a function of measuring a property.

According to the case, the control unit 24 is thus able to perform one or more of the above functions.

As a result, the control unit 24 includes one or more subunits able to perform one or both of the modification and measurement functions.

Some examples are described below.

A ferroelectric skyrmion generation subunit is a first example of a subunit.

A generation subunit comprises an electrical source.

Alternatively, the generation subunit comprises an optical source.

Another example of a ferroelectric skyrmion destruction subunit.

The destruction subunit comprises an electrical source or an optical source.

Yet another example of a subunit is a subunit for adjusting at least one property of the ferroelectric skyrmions.

It should also be noted that, according to the amplitude, duration and direction of the applied electric field (of the order of 0.01 V/nm to 10 V/nm) or the type of optical pulses, the subunit performs either a generation or destruction mechanism.

Therefore, provided that it is possible to control the electrical or optical source, the control unit 24 can include a single electrical or optical source the function of which is both to generate and destroy the ferroelectric skyrmions.

According to one particular embodiment, the adjustment subunit is able to control the temperature.

According to another embodiment, the adjustment subunit is able to control voltage stress.

A subunit for reading at least one property of the ferroelectric skyrmions is another example of a subunit that can form part of the control unit.

By way of illustration, the reading subunit is able to measure resistance.

Alternatively, the reading subunit is suitable for measuring an optical index.

According to another alternative, the reading subunit comprises an optical source.

The operation of the tunnel junction 12 is deduced from the operation of a ferroelectric tunnel junction, which is now described.

In a ferroelectric tunnel junction, the resistance level is directly related to the fraction of the total number of dipoles pointing toward one or other of the electrodes. In both extreme cases, the resistance is minimal when the polarization is homogeneous and points (for example) toward the upper electrode, and maximal when it points to the lower electrode. In a simplified case, if domains are present, within them polarization points toward one of the two electrodes, and outside them polarization points according to the opposite direction. The application of an electrical voltage modifies the domain structure and therefore the fraction of dipoles pointing toward one of the electrodes, leading to a variation in resistance. This variation can be quasi-continuous, leading to memristor-like behavior. The term ferroelectric memristor is sometimes used to designate such behavior.

The tunnel junction 12 differs from this operation in that the domains are ferroelectric skyrmions 22.

As with the domains of a ferroelectric tunnel junction, the ferroelectric skyrmions 22 are sensitive to the electric field. But, in this case, the electric field only has the effect of creating or annihilating, or even displacing, the ferroelectric skyrmions 22. Under the application of an electric field (or light beam), some ferroelectric skyrmions 22 disappear or are created, so that the number of ferroelectric skyrmions 22 existing at remanence can be adjusted electrically. The electric field does not have the effect of deforming the ferroelectric skyrmions 22 due to their topological properties. Thus, the fraction of dipoles pointing toward one of the electrodes 14 or 16 is determined by the number of ferroelectric skyrmions 22, a “quantified” integer.

Consequently, the resistance of the device can only adopt a certain number of resistance levels, depending on the number of ferroelectric skyrmions 22 present.

In other words, according to the number of ferroelectric skyrmions 22 present, the resistance of the tunnel junction will be modified, which will allow several discrete resistance levels to be encoded.

To summarize, it thus appears that a ferroelectric tunnel junction presents a resistance that depends on the structure of the ferroelectric domains in the barrier. The tunnel junction 12 uses ferroelectric skyrmions as ferroelectric domains, the topological character of which enhances the stability of the configuration. According to the number of skyrmions present in the barrier 18, adjusted by applying an electrical voltage, the resistance of the tunnel junction 12 is modulated, allowing the tunnel junction 12 to be used as a multi-state (multi-bit) memory element.

The tunnel junction 12 thus allows greater stability at intermediate resistance levels, making the use of error correction codes unnecessary.

This allows a faster, error-limited multi-state memory 10 to be obtained.

Compared with other non-volatile memory technologies such as those based on memristors, the memory 10 also presents good endurance, high operating frequency, high resistance levels and low write energy.

According to another embodiment, the barrier 18 is no longer a single layer, but includes several layers forming a heterostructure.

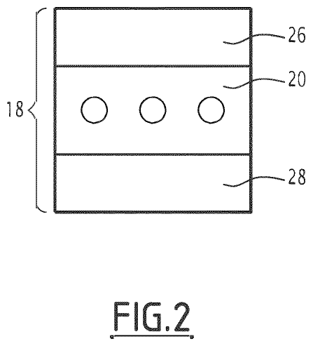

Thus, as illustrated in FIG. 2, the barrier 18 also includes two dielectric layers 26 and 28.

The dielectric material forming each dielectric layer 26 or 28 is selected from the list constituted of SrTiO₃, KTaO₃, LaAIO₃, (Dy, Tb, Gd, Sm, Nd, La)ScO₃, NdGaO₃, HfO₂, ZrO₂, Y₂O₃ and Al₂O₃. The notation (Dy, Tb, Gd, Sm, Nd, La)ScO₃ means XScO₃ where X is selected from among Dy, Tb, Gd, Sm, Nd and La.

The ferroelectric layer 20 is interposed between the two dielectric layers 26 and 28 so that the dielectric layers 26 and 28 and the ferroelectric layer 20 form a stack of superimposed layers along a stacking direction.

Alternatively, the barrier layer 18 is formed by a superlattice of dielectric layers 26 or 28 and ferroelectric layers 20, in other words, a pattern formed by at least one dielectric layer 26 or 28 and a ferroelectric layer 20 that is repeated.

For example, the pattern is a bilayer formed by a dielectric layer 26 or 28 and a ferroelectric layer 20. This allows a stack to be formed by alternating dielectric layers 26 or 28 and ferroelectric layers 20.

This allows a tunnel junction 12, presenting the same properties as the tunnel junction shown in FIG. 1, to be obtained.

In each case, due to the competition between dipolar energy and anisotropy induced by the heterostructure, the dipoles are not organized as traditionally in the form of domains but adopt highly non-collinear configurations including skyrmions.

More generally, any configuration that allows to obtain Bloch or Néel walls to be generated between two ferroelectric domains instead of Ising walls (in other words. with no change in polarization direction, but with a decrease in its norm between two domains) is conceivable.

The configuration could be obtained by taking several factors into account, among which, temperature.

Temperature is to be taken into account because the ferroelectric domain wall can be considered as a confined ferroelectric state with its own transition temperature. Thus, there is an order temperature in the wall (less than the critical temperature of the barrier material to be formed) above which a Bloch to Ising transition occurs. Simulations indicate a phase transition in the Bloch walls of PbTiO₃ films around 100 K lower than in the material.

The coexistence of polymorphs with different symmetries in the vicinity of the morphotropic phase boundary can also be taken into account in low-symmetry systems (for example, monoclinic), allowing polarization rotations in the walls. For example, this can involve Neel walls in PbZrₓTi₁₋ₓO₃ crystals, where the wall has monoclinic symmetry, and the domains are tetragonal.

Growth can also be taken into account in the form of epitaxial stress. In fact, epitaxial stress can modify ferroelastic energy: biaxial compression will favor domains the polarization of which is orthogonal to the plane of the layers, and therefore the appearance of 180° walls. On the other hand, tensile stress will favor domains the polarization of which is in the plane of the thin layer, and therefore the appearance of 90° walls, the latter presenting an Ising character. In the case of low tensile stress (as with DyScO₃), PbTiO₃ will have a mixed domain structure. Thus, this ingredient allows to have fairly close energies between in-plane and out-of-plane ferroelectric domains, again favoring the stabilization of Néel or Bloch walls to obtain skyrmions.

Electrostatic (dipolar) energy control can also be used to generate a non-zero polarization gradient at the interface, favoring the creation of nano-domains with 180° walls and topological charges.

The energy gradient within the layers can also be used to control the rotation of the polarization vector or its amplitude. Chiral walls will be obtained by seeking to rotate the polarization vector It is thus possible to obtain different configurations with selected conditions allowing the ferroelectric skyrmions 22 to be obtained.

However, other topologically protected structures are also possible.

For example, instead of a skyrmion, the ferroelectric layer 20 includes antiskyrmions.

Combinations are also possible, such as a biskyrmion, a skyrmonium and an antiferromagnetic skyrmion.

A skyrmionium is a pair of skyrmions intricate with each other but with opposite topological charges, whereas the antiferromagnetic skyrmion is a set of two skyrmions with opposite magnetizations that are superimposed on each other.

Other dipolar textures with a different topological character to skyrmions, such as merons or hopfions, can also be used as topologically protected structures.

Thus, the topologically protected structure can be chosen from a skyrmion, an antiskyrmion, a meron, an anmeron, a hopfion, a biskyrmion, a skyrmonium or an antiferromagnetic skyrmion.

In each case, each topologically protected structure presents a size of between 1 nm and 100 nm.

Furthermore, the number of topologically protected structures is less than or equal to 10,000.

Other embodiments can be obtained by combining the embodiments described above.

In each of these embodiments obtained by combination, the tunnel junction 12 presents a barrier layer 18 comprising a ferroelectric layer 18 with at least one topologically protected structure 22 presenting properties, the tunnel junction 12 further comprising a unit 24 for monitoring the properties of the at least one topologically protected structure.

This allows to obtain multi-level resistive memories in which the stability of intermediate resistance levels is enhanced by topological protection. These memories are thus based on ferroelectric tunnel junctions the resistance level of which is determined by specific ferroelectric domain configurations possessing a topological character corresponding to the presence of topologically protected structures such as, for example, the ferroelectric skyrmions 22.

1. A tunnel junction presenting a stack formed by a barrier and two electrodes the barrier comprising a layer of a ferroelectric material, referred to as a ferroelectric layer, the barrier presenting a thickness less than or equal to 15 nanometers, the ferroelectric layer comprising at least one topologically protected structure presenting properties, the tunnel junction further comprising a control unit for monitoring the properties of said at least one topologically protected structure.

2. The tunnel junction according to claim 1, wherein said at least one topologically protected structure is comprises a member of the group consisting of: a skyrmion, an antiskyrmion, a meron, an anmeron, a hopfion, a biskyrmion, a skyrmonium and an antiferromagnetic skyrmion,

3. The tunnel junction according to claim 1, wherein the number of said at least one topologically protected structure is less than or equal to 10,000 and each topologically protected structure presents a size of between 1 nanometer and 100 nanometers.

4. The tunnel junction according to claim 1, wherein said control unit comprises at least one subunit chosen from among a subunit for generating said at least one topologically protected structure and a subunit for destroying said at least one topologically protected structure.

5. The tunnel junction according to claim 1, wherein said control unit includes a subunit for adjusting at least one property of said at least one topologically protected structure the adjustment subunit controlling temperature or for controlling stresses.

6. The tunnel junction according to claim 4, wherein each of said at least one subunit comprises an electrical source or an optical source.

7. The tunnel junction according to claim 1, further comprising a subunit for reading at least one property of said at least one topologically protected structure, the subunit for reading measuring a resistance or an optical index.

8. The tunnel junction according to claim 1, wherein said ferroelectric layer comprises a ferroelectric material selected from the group consisting of Ba₁₋ₓSrₓTIO₃, PbTiO₃, Bi₁₋ₓLaₓFeO₃, PbZrₓTi₁₋ₓO₃, Hf₁₋ₓZrₓO₂ or KNbO₃, x being a variable between 0 and 1.

9. The tunnel junction according to claim 1, wherein said barrier comprises at least one dielectric layer in contact with said ferroelectric layer, each dielectric layer comprising a material selected from the list constituted group consisting of SrTiO₃, KTaO₃, LaAlO₃, (Dy, Tb, Gd, Sm, Nd, La)ScO₃, NdGaO₃, HfO₂, ZrO₂, Y₂O₃ and Al₂O₃,

10. The tunnel junction according to claim 1, wherein said barrier is a stack of several identical patterns, each pattern comprising at least one ferroelectric layer and a dielectric layer each ferroelectric layer comprising a member of the group consisting of Ba₁₋ₓSrₓTiO₃, PbTiO₃, Bi₁₋ₓLaₓFeO₃, PbZrₓTi₂₋ₓO₃, Hf₁₋ₓZrₓO₂ and KNbO₃, x being a variable between 0 and 1, and each dielectric layer comprising a member of the group consisting of SrTiO₃, KTaO₃, LaAlO₃, (Dy, Tb, Gd, Sm, Nd, La)ScO₃, NdGaO₃, HfO₂, ZrO₂, Y₂O₃ and Al₂O₃.

11. The tunnel junction according to claim 1, wherein said electrodes comprise members of the group consisting of La₁₋ₓSrₓMnO₃, La₁₋ₓCaₓMnO₃, Ca₁₋ₓCeₓMnO₃, BaₓS₁₋ₓRuO₃, BaPbO₃, LaNiO₃, La₁₋ₓSrₓTiO₃, RuO₂, conductive indium tin oxide, TiN, Pt, Au and Pd, x being a variable between 0 and 1.

12. A memory comprising a tunnel junction according to claim 1.
